(19) United States
(12) Patent Application Publication
(10) Pub. No.: US 2024/0385646 A1
(43) Pub. Date: Nov. 21, 2024

(54) DISPLAY APPARATUS

(71) Applicants: NEC CORPORATION, Minato-ku, Tokyo (JP); NEC Platforms., Ltd., Kawasaki-shi, Kanagawa (JP)

(72) Inventors: Shinji FUNAI, Tokyo (JP); Takahiro MATSUI, Tokyo (JP); Hironobu MOCHIZUKI, Kanagawa (JP); Naoto OTA, Kanagawa (JP)

(73) Assignees: NEC CORPORATION, Minato-ku, Tokyo (JP); NEC Platforms, Ltd, Kawasaki-shi, Kanagawa (JP)

(21) Appl. No.: 18/692,935

(22) PCT Filed: Sep. 2, 2022
(86) PCT No.: PCT/JP2022/033086

§ 371 Date: Mar. 18, 2024

(30) Foreign Application Priority Data
Sep. 30, 2021 (JP) 2021-160789

(51) Int. Cl. G06F 1/16

(52) U.S. Cl. CPC G06F 1/1601

(57) ABSTRACT

A display apparatus (10) includes a display (110) and a housing (120). The housing (120) is one example of a support member, and supports the display (110). The housing (120) includes a base (140). The base (140) includes, on an upper surface thereof, a positioning portion, for example, a recess portion (142) that positions a first input device (20). The recess portion (142) is larger than the first input device (20) in a top plan view. The first input device (20) is, for example, a keyboard.

### TECHNICAL FIELD

The present invention relates to a display apparatus.

### BACKGROUND ART

It is often a case that a computer is used together with another apparatus such as a display apparatus and an input apparatus. Therefore, various apparatuses are disposed around a computer. Patent Document 1 describes a computer integrally formed with a display, wherein a recess portion is formed in a stand portion, and a keyboard is accommodated within the recess portion.

### RELATED DOCUMENT

### Patent Document

Patent Document 1: Japanese Patent Application Publication No. 2000-148297

### SUMMARY OF INVENTION

### Technical Problem

As described in Patent Document 1, when an input device such as a keyboard is made placeable on a base of a display, it is easy to organize a periphery of a computer. The present inventor of the present application has conceived that it is easy to place an input device on a base when a position of the input device is easily determined on the base of a display.

One example of objects of the present invention is to make it easy to determine a position of an input device on a base of a display.

### Solution to Problem

One aspect of the present invention provides a display apparatus including:
a display; and
a support member that supports the display, wherein
the support member includes a base, and
the base includes, on an upper surface thereof, a positioning portion that positions a first input device.

### Advantageous Effects of Invention

According to one aspect of the present invention, it is easy to determine a position of an input device on a base of a display.

### BRIEF DESCRIPTION OF DRAWINGS

FIG. 1 It is a front view of a display apparatus according to a first example embodiment.

FIG. 2 is a rear view of the display apparatus.

FIG. 3 It is a side view of the display apparatus.

FIG. 4 It is a perspective view of the display apparatus.

FIG. 5 It is a side view illustrating a configuration of main parts of a display apparatus according to a second example embodiment.

FIG. 6 It is a perspective view of main parts of the display apparatus.

FIG. 7 It is a side view illustrating a configuration of main parts of a display apparatus according to a third example embodiment.

FIG. 8 It is a perspective view of main parts of the display apparatus.

FIG. 9 It is a diagram illustrating a modification example of FIG. 8.

FIG. 10 It is a diagram illustrating an arrangement of a first input device when a user of the display apparatus uses the first input device.

FIG. 11 It is a side view illustrating a configuration of main parts of a display apparatus according to a fourth example embodiment.

FIG. 12 It is a diagram illustrating a modification example of FIG. 11.

FIG. 13 It is a side view of a display apparatus according to a fifth example embodiment.

FIG. 14 It is a perspective view of a display apparatus according to a sixth example embodiment.

FIG. 15 It is a perspective view of the display apparatus.

### DESCRIPTION OF EMBODIMENTS

Hereinafter, example embodiments according to the present invention are described by using the drawings. Note that, in all drawings, a similar constituent element is indicated by a similar reference sign, and description thereof will not be repeated as appropriate.

### First Example Embodiment

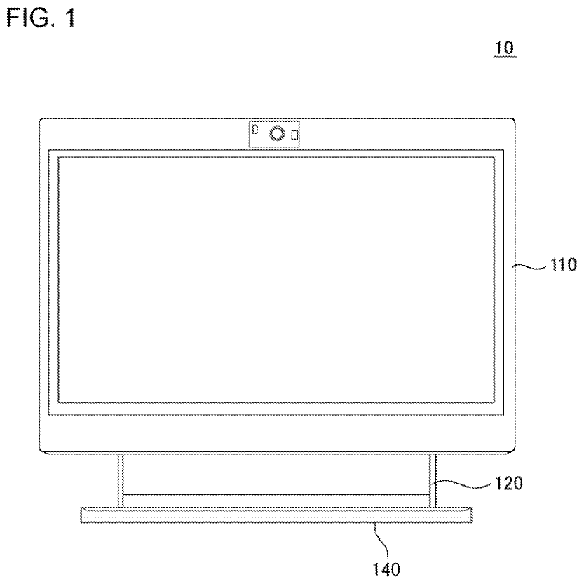

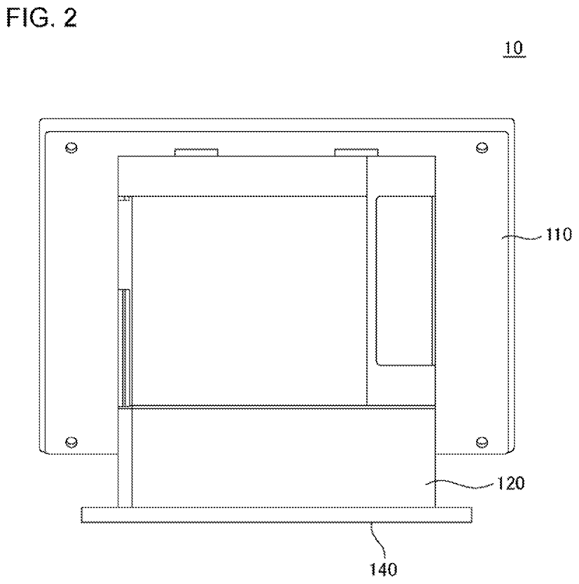

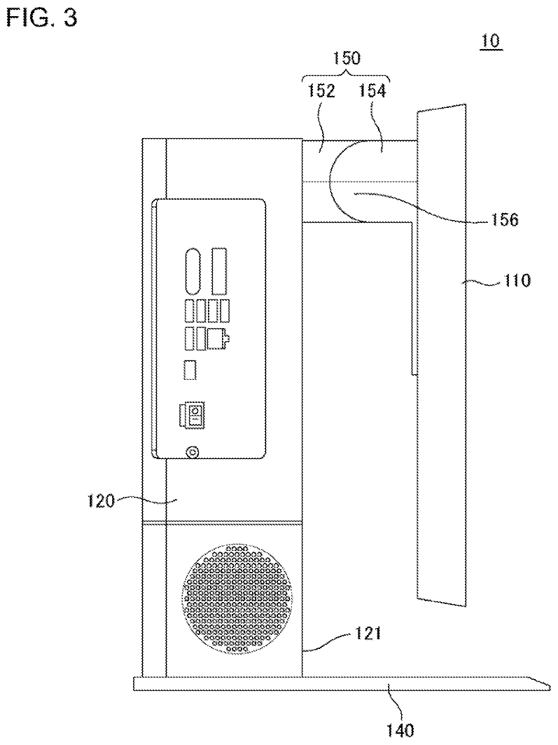

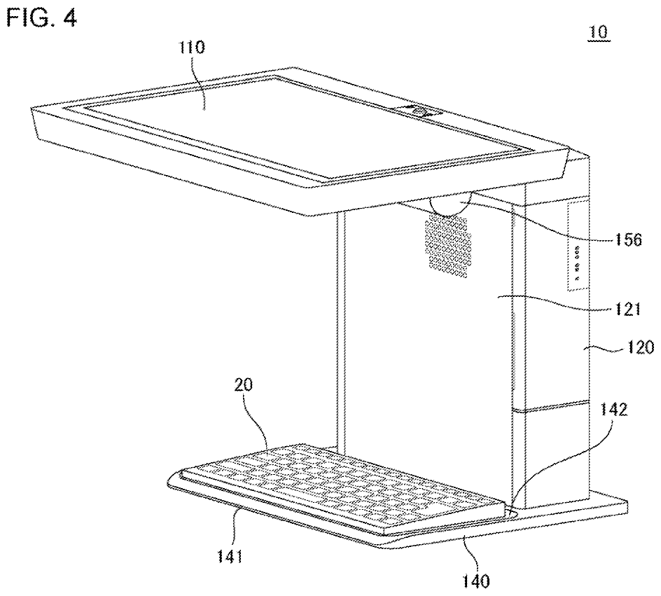

FIG. 1 is a front view of a display apparatus 10 according to a present example embodiment, FIG. 2 is a rear view of the display apparatus 10, and FIG. 3 is a side view of the display apparatus 10. Further, FIG. 4 is a perspective view of the display apparatus 10. In FIG. 4, a display 110 faces upward.

As illustrated in FIGS. 1 to 4, the display apparatus 10 includes the display 110 and a housing 120. A control unit is provided inside the housing 120. The control unit includes, for example, a central processing unit (CPU) and a memory, and performs various pieces of arithmetic operation processing and control processing. One example of the control processing is control of the display 110. As illustrated in FIGS. 1 to 4, the display 110 is mounted on a side surface of the housing 120.

The housing 120 is, for example, a housing of a desktop type computer. Further, various electronic components constituting the computer, for example, a CPU, a memory, a storage device, and the like are accommodated inside the housing 120. One example of the computer is a store computer that manages a product in a store, but may be a terminal for use in another purpose, for example, a point of sales (POS) terminal or a personal terminal.

The display 110 is mounted on the housing 120. In the example illustrated in FIGS. 1 to 4, a back surface of the display 110 is mounted on a front surface of the housing 120 in such a way as to face a largest surface 121 of the housing 120. A length of the display 110 in a vertical direction is equal to a size slightly shorter than a height of the surface 121. Further, a horizontal width of the display 110 may be larger or smaller than the horizontal width of the surface 121. In the example illustrated in FIGS. 1 to 4, the display 110 is mounted to be movable with respect to the housing 120.

Specifically, as illustrated in FIGS. 3 and 4, the display 110 is mounted on the surface 121 of the housing 120 via a connecting portion 150. More specifically, the connecting portion 150 includes a first member 152 and a second member 154. The first member 152 is fixed to the surface 121 of the housing 120, and the second member 154 is fixed to the back surface of the display 110. Further, the first member 152 and the second member 154 are connected to each other via a hinge portion 156.

The hinge portion 156 is provided along an upper side of the display 110. Further, the hinge portion 156 also extends along an upper side of the surface 121. Therefore, the display 110 is rotatable with respect to the housing 120 around the upper side of the display 110. Note that, the hinge portion 156 may be provided along another side of the display 110, for example, along a horizontal side thereof.

The hinge portion 156 may include a lock mechanism. The lock mechanism fixes the hinge portion 156 at a predetermined angle (or at a desired angle). Providing the lock mechanism enables to fix an angle of the display 110 at a predetermined angle, or at any angle desired by a user. As one example, when it is not necessary to rotate the display 110, for example, when maintenance or the like of an inner portion of the housing 120 is not necessary, the hinge portion 156 is fixed by the lock mechanism. Further, when it is necessary to rotate the display 110, for example, when maintenance or the like of an inner portion of the housing 120 is necessary, the lock mechanism of the hinge portion 156 is released. In this case, the display 110 is made rotatable. Note that, when the display 110 is fixed at a predetermined angle, the predetermined angle is, for example, each of an angle at which the display 110 becomes vertical, and an angle at which the display 110 faces upward, for example, an angle being equal to more than a horizontal angle, but the present example embodiment is not limited thereto.

Note that, when the hinge portion 156 does not include the lock mechanism, the hinge portion 156 is constantly rotatable.

Further, at least a part of the surface 121 is made detachable. Hereinafter, the part is described as a lid portion. The lid portion does not include a portion to which the first member 152 of the connecting portion 150 is fixed. Further, detaching the lid portion enables to perform exchange or the like of an electrical component (e.g., a component constituting the control unit) accommodated inside the housing 120. Note that, when the hinge portion 156 includes the lock mechanism, since the display 110 can be fixed in a state where the display 110 faces upward, the above-described work can be performed more easily.

Further, as illustrated in FIGS. 1 to 4, a base 140 is provided on a lower surface of the housing 120. Note that, the base 140 is wider than the lower surface of the housing 120. Therefore, even when the display 110 is mounted on the housing 120, the housing 120 does not easily fall down.

Further, an upper surface of the base 140 includes a positioning portion that positions a first input device 20. The first input device 20 is a device, for example, a keyboard and a mouse, performing an input to the control unit inside the housing 120. Further, the positioning portion includes a recess portion 142. A planar shape of the recess portion 142 is larger than that of the first input device 20. The horizontal width of the recess portion 142 is larger than the horizontal width of the first input device 20, and a difference between the horizontal widths is, for example, 1 cm or more and 3 cm or less. Further, the vertical width of the recess portion 142 is larger than the vertical width of the first input device 20, and a difference between the vertical widths is, for example, 1 cm or more and 3 cm or less. Therefore, the first input device 20 is accommodated in the recess portion 142 in a plan view. In this state, the first input device 20 is positioned by an inner wall of the recess portion 142.

In the example illustrated in these drawings, an edge of the base 140 protrudes upward, thereby forming a wall portion 141. Further, the recess portion 142 is an area surrounded by the wall portion 141. The height of the wall portion 141 is, for example, 5 mm or more and 2 cm or less.

As described above, according to the present example embodiment, when not using the first input device 20, a user of the display apparatus 10 can place the first input device 20 on the base 140. Further, the upper surface of the base 140 includes the recess portion 142 for positioning the first input device 20. Therefore, it is easy to determine a position of the first input device 20 on the base 140.

### Second Example Embodiment

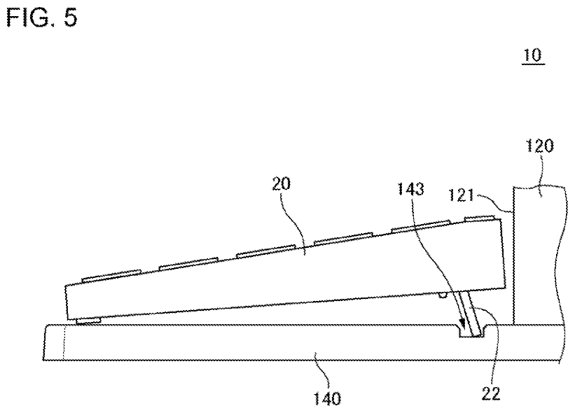

FIG. 5 is a side view illustrating a configuration of main parts of a display apparatus 10 according to a present example embodiment. The display apparatus 10 illustrated in FIG. 5 is similar to the display apparatus 10 according to the first example embodiment except for a configuration of a positioning portion for a first input device 20.

In FIG. 5, the positioning portion for the first input device 20 includes a recess portion 143. The recess portion 143 is a groove, and has a size capable of inserting a part of a lower surface of the first input device 20.

Specifically, the lower surface of the first input device 20 includes a protruding portion 22. The protruding portion 22 is rotatable, for example, around an end portion of the protruding portion 22, and is settable to both of a state where the protruding portion 22 is along the lower surface of the first input device 20, and a state where the protruding portion 22 protrudes from the lower surface of the first input device 20. Further, the protruding portion 22 is inserted into the recess portion 143 in a state where the protruding portion 22 protrudes from the lower surface of the first input device 20.

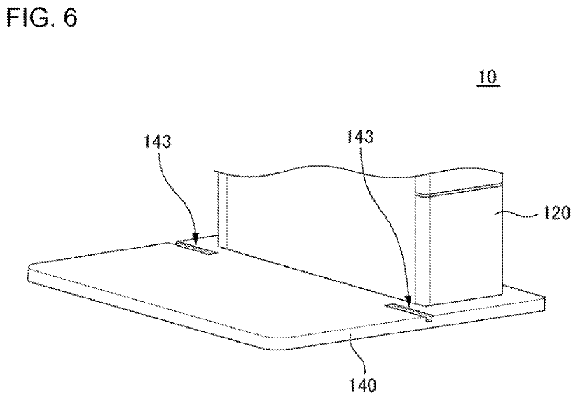

An orientation of the recess portion 143 is determined as necessary according to an orientation of the protruding portion 22. In the example illustrated in FIG. 5, the recess portion 143 is substantially in parallel to a surface 121. Further, a length of the recess portion 143 is determined as necessary according to a position of the protruding portion 22 in a width direction of the display 110, specifically, in a left-right direction of a user of the display apparatus 10. For example, as illustrated in a perspective view in FIG. 6, the recess portion 143 may be formed only in a part of a base 140 in the left-right direction of a user. Further, the recess portion 143 may be formed in the entirety of the base 140 in the left-right direction of a user. However, in this case, the recess portion 143 may not reach a side surface of the base 140.

Also according to the present example embodiment, it is easy to determine a position of the first input device 20 on the base 140.

### Third Example Embodiment

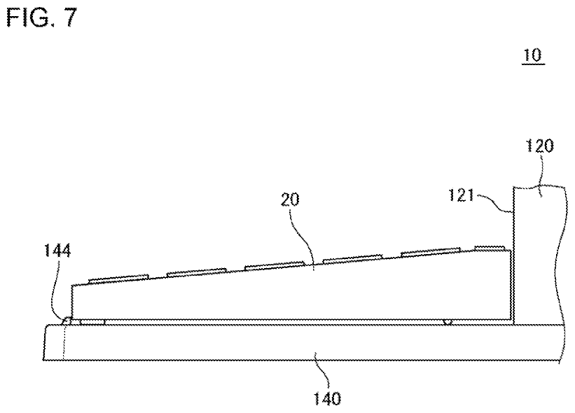

FIG. 7 is a side view illustrating a configuration of main parts of a display apparatus 10 according to a present example embodiment. The display apparatus 10 illustrated in FIG. 7 is similar to the display apparatus 10 according to the first example embodiment except for a configuration of a positioning portion for a first input device 20.

In FIG. 7, the positioning portion for the first input device 20 includes a protruding portion 144. The first input device 20 is positioned by coming into contact with the protruding portion 144 or a surface 121 of a housing 120.

Specifically, the housing 120 extends upward from a base 140, and serves as a pillar portion that supports a display 110. Further, a gap between a side surface of the protruding portion 144 on a surface—121 side of the housing 120, and the surface 121 is larger than a width of the first input device 20. Further, the first input device 20 is disposed between the protruding portion 144 and the surface 121. Thus, a position of the first input device 20 is determined on the base 140. Note that, a difference between the gap of the protruding portion 144 and the surface 121, and a length of the first input device 20 in a left-right direction in FIG. 7, specifically, a length in a direction that intersects with the surface 121 is, for example, 5 mm or more and 3 cm or less.

However, when a coefficient of friction of the protruding portion 144 is larger than a coefficient of friction of an upper surface of the base 140, the gap between the protruding portion 144 and the surface 121 may be smaller than the width of the first input device 20. In this case, the position of the first input device 20 is determined by abutment of a lower surface of the first input device 20 against an upper surface of the protruding portion 144. Note that, a high frictional portion may be formed on a part of the upper surface of the base 140, in place of the protruding portion 144. The high frictional portion is an area where a coefficient of friction is large, as compared with another portion on the upper surface of the base 140. An upper surface of the high frictional portion may be made flush with an upper surface on another portion of the base 140.

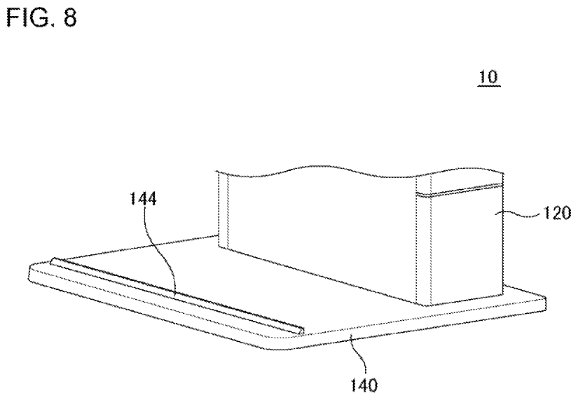

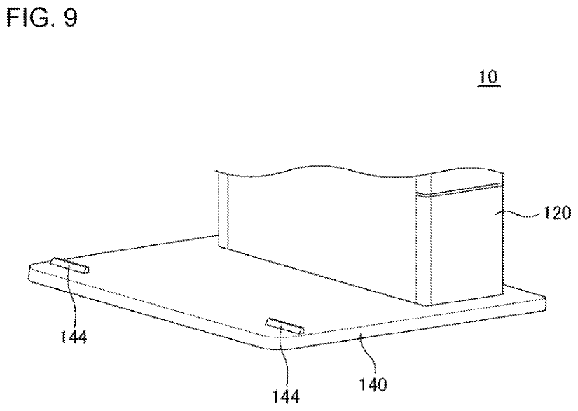

As illustrated in a perspective view in FIG. 8, the protruding portion 144 may be formed on the entirety of the base 140 in the left-right direction of a user. Further, as illustrated in a perspective view in FIG. 9, the perspective view of the protruding portion 144 may be formed only on a part of the base 140.

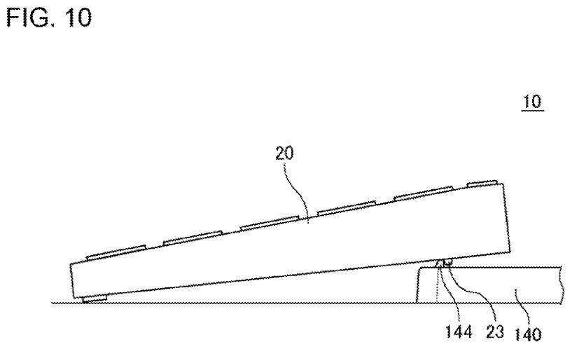

FIG. 10 is a diagram illustrating an arrangement of the first input device 20 when a user of the display apparatus 10 uses the first input device 20 in the present example embodiment. In the example illustrated in FIG. 10, the first input device 20 includes a protruding portion 23 at a position near a side surface on an opposite side to a side surface on a user side, for example, within a range of 3 cm from a side surface on the opposite side. The protruding portion 23 is one example of a second protruding portion. Further, the side surface of the protruding portion 23 on the user side comes into contact with the protruding portion 144 formed on the base 140. The protruding portion 144 is one example of a first protruding portion. Meanwhile, an end portion on the lower surface of the first input device 20 on the user side comes into contact with a desk on which the base 140 is placed. This allows the first input device 20 to be positioned by the base 140 also in a state of use by a user.

Also according to the present example embodiment, it is easy to determine the position of the first input device 20 on the base 140.

### Fourth Example Embodiment

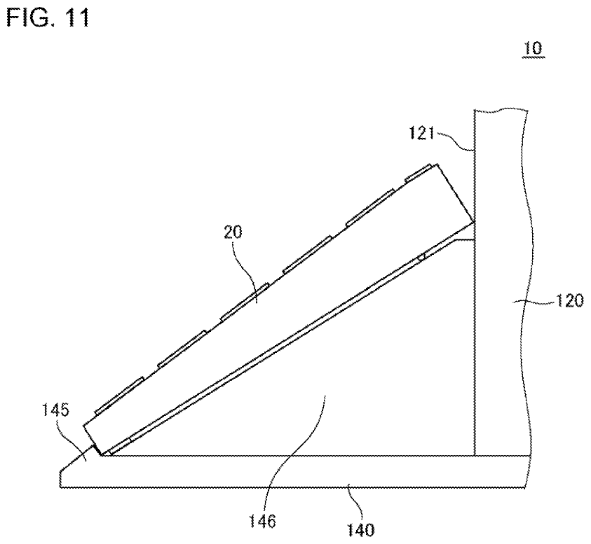

FIG. 11 is a side view illustrating a configuration of main parts of a display apparatus 10 according to a present example embodiment. The display apparatus 10 illustrated in FIG. 11 is similar to the display apparatus 10 according to the first example embodiment except for a configuration of a positioning portion for a first input device 20.

In the example illustrated in FIG. 11, a base 140 includes a protruding portion 145. Further, a gap between a side surface of the protruding portion 145 on a surface—121 side of a housing 120, and a surface 121 is smaller than a width of the first input device 20. Further, a support portion 146 is formed between the protruding portion 145 on an upper surface of the base 140, and the surface 121. A lower surface of the support portion 146 comes into contact with an upper surface of the base 140, and an upper surface of the support portion 146 is tilted, as the support portion 146 extends upward from the protruding portion 145 toward the surface 121. Further, an end portion of the support portion 146 on a protruding-portion—145 side is lower than an upper end of the protruding portion 145. Note that, preferably, the protruding portion 145 may be formed on an edge on the upper surface of the base 140 on a user side.

The first input device 20 is disposed on the upper surface of the support portion 146. In this state, an end portion of the first input device 20 on the protruding-portion—145 side comes into contact with a side surface of the protruding portion 145. In this way, the first input device 20 is positioned.

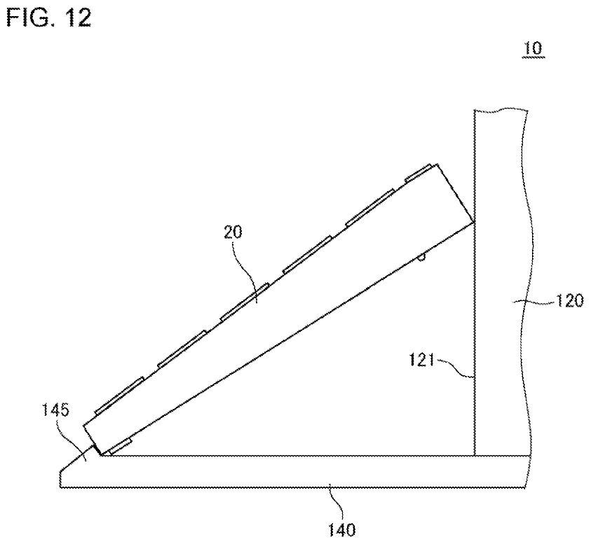

Note that, as illustrated in a side view in FIG. 12, the support portion 146 may be omitted. In this case, the first input device 20 is sandwiched between the protruding portion 145 and the surface 121 in a tilted state.

Also according to the present example embodiment, it is easy to determine a position of the first input device 20 on the base 140. Further, when the protruding portion 145 is formed on an edge on the upper surface of the base 140 on the user side, a depth of the base 140 can be made smaller than the depth of the first input device 20.

### Fifth Example Embodiment

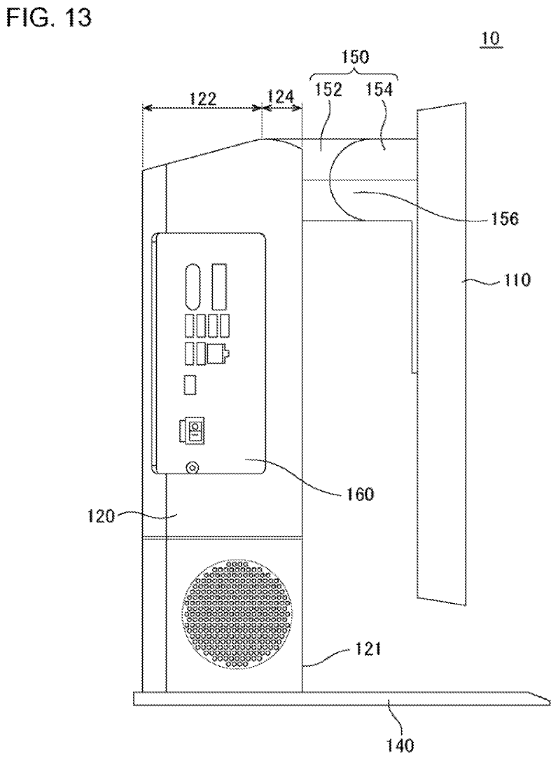

FIG. 13 is a side view of a display apparatus 10 according to a present example embodiment. The display apparatus 10 illustrated in FIG. 13 is similar to that according to any of the first to fourth example embodiments except for a shape of an upper surface of a housing 120.

In the example illustrated in FIG. 13, the upper surface of the housing 120 includes a first slope portion 122. The first slope portion 122 is connected to a side surface of the housing 120 on an opposite side to a display 110 in a thickness direction of the housing 120, specifically, in a left-right direction in FIG. 13. Further, the first slope portion 122 is tilted downward, as the first slope portion 122 is away from the display 110. The first slope portion 122 occupies 50% or more with respect to the upper surface of the housing 120 in the thickness direction of the housing 120.

Further, a portion on the upper surface of the housing 120 except for the first slope portion 122 in the thickness direction of the housing 120 serves as a second slope portion 124. The second slope portion 124 is connected to a surface 121 of the housing 120. Further the second slope portion 124 is tilted upward, as the second slope portion 124 is away from the display 110. Further, the first slope portion 122 occupies 50% or more, preferably 60% or more with respect to the upper surface of the housing 120 in a plan view.

Note that, preferably, a boundary of the first slope portion 122 and the second slope portion 124 may be made gentle.

Forming the first slope portion 122 on the upper surface of the housing 120 makes it impossible to place an object, for example, a PET bottle containing beverage, on the upper surface of the housing 120. Thus, a failure of an electronic component inside the housing 120 due to an object placed on the upper surface of the housing 120 can be suppressed.

Note that, also according to the present example embodiment, a base 140 of the display apparatus 10 includes a positioning portion for positioning a first input device 20. Therefore, it is easy to determine a position of the first input device 20 on the base 140.

### Sixth Example Embodiment

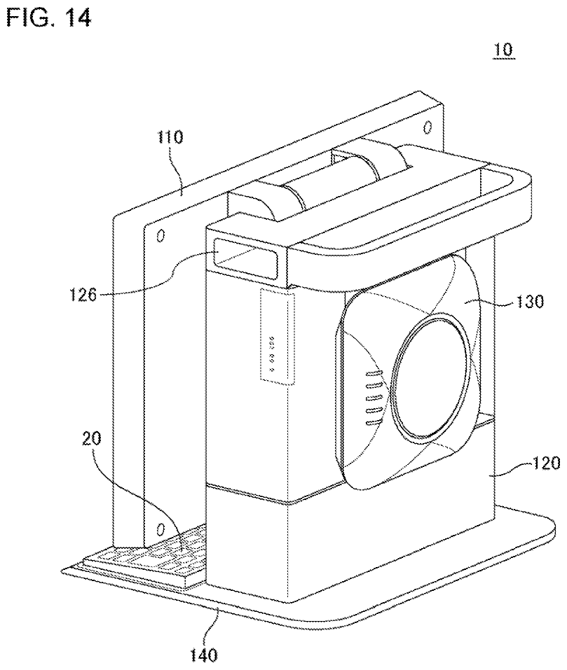

FIG. 14 is a perspective view of a display apparatus 10 according to a present example embodiment. The display apparatus 10 illustrated in FIG. 14 is similar to that according to any of the first to fifth example embodiments except for the following point.

First, a wireless relay apparatus 130 is fixed to one of side surfaces of a housing 120 on an opposite side to a surface 121. The wireless relay apparatus 130 is, for example, a wireless access point, a wireless local area network (LAN) router, a wireless repeater, a HUB, a router, or a separator, and communicates with a wireless terminal in accordance with a communication standard such as Wi-Fi (registered trademark). The wireless terminal to be used herein, for example, may be a smartphone, or may be a tablet terminal. Further, the wireless terminal may be a fixed type terminal having a wireless communication function. Examples of the terminal include a notebook type personal computer, a desktop type personal computer, a printer, a storage, a display of a TV set or the like, a smart speaker, audio equipment, and a home appliance such as a refrigerator. Further, the wireless relay apparatus 130 connects the wireless terminal to a wired line (e.g., a LAN line), or a high-speed wireless communication line (e.g., long term evolution (LTE) or a local 5G line).

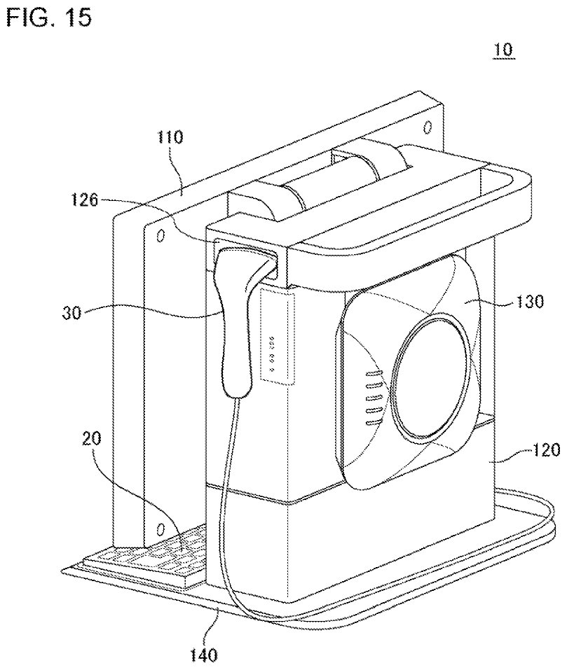

Further, one of the side surfaces of the housing 120 that does not oppose to any of the display 110 and the wireless relay apparatus 130 includes a recess portion 126. As illustrated in FIG. 15, the recess portion 126 is formed to hold a second input device 30. In the example illustrated in FIG. 15, the second input device 30 is a handy scanner, and a reading portion of code information is made wider than that of other portion. Further, the reading portion of the second input device 30 is fitted into the recess portion 126.

Note that, the display apparatus 10 may include other structure such as a hook or a magnet that holds the second input device 30, in place of the recess portion 126.

Further, the display apparatus 10 may include only one of the wireless relay apparatus 130 and the recess portion 126.

Also according to the present example embodiment, it is easy to determine a position of a first input device 20 on a base 140. Further, it is also possible to hold the second input device 30 on the housing 120.

In the foregoing, the example embodiments according to the present invention have been described with reference to the drawings, however, these are examples of the present invention, and various configurations other than the above can also be adopted. Further, each of the above-described example embodiments can be combined, as far as contents do not conflict with each other.

A part or all of the above-described example embodiments may also be described as the following supplementary notes, but is not limited to the following.
1. A display apparatus including:
   a display; and
   a support member that supports the display, wherein
   the support member includes a base, and
   the base includes, on an upper surface thereof, a positioning portion that positions a first input device.
2. The display apparatus according to supplementary note 1, wherein
   the positioning portion includes a recess portion formed in the upper surface.
3. The display apparatus according to supplementary note 2, wherein
   the recess portion is larger than the first input device in a top plan view.
4. The display apparatus according to supplementary note 2, wherein
   the first input device includes a protruding portion, and
   the recess portion positions the first input device by accepting the protruding portion.
5. The display apparatus according to supplementary note 1, wherein
   the positioning portion includes an anti-slip portion having a coefficient of friction larger than that of the upper surface of the base.
6. The display apparatus according to supplementary note 1, wherein
   the positioning portion includes a first protruding portion.
7. The display apparatus according to supplementary note 6, wherein
   the support member includes a pillar portion extending upward from the base, and
   the first input device is disposed between the first protruding portion and the pillar portion.
8. The display apparatus according to supplementary note 6 or 7, wherein
   the first input device is a keyboard,
   a lower surface of the keyboard includes a second protruding portion, and,
   when being used the keyboard, the keyboard is arranged in such a way that a side surface of the first protruding portion and a side surface of the second protruding portion come into contact with each other.
9. The display apparatus according to any one of supplementary notes 1 to 8, further including:
   a control unit that controls the display; and
   a housing that accommodates the control unit, wherein
   at least a part of a back surface of the display faces a side surface of the housing,
   an upper surface of the housing includes a slope portion being tilted in a thickness direction of the display, and
   a ratio of the slope portion with respect to the upper surface is 50% or more.
10. The display apparatus according to any one of supplementary notes 1 to 9, further including:
   a control unit that controls the display; and
   a housing that accommodates the control unit, wherein
   a side surface of the housing includes a recess portion that holds a second input device.

This application is based upon and claims the benefit of priority from Japanese patent application No. 2021-160789, filed on Sep. 30, 2021, the disclosure of which is incorporated herein in its entirety by reference.

### REFERENCE SIGNS LIST

10 Display apparatus
20 First input device
22 Protruding portion
23 Protruding portion (second protruding portion)
30 Second input device
110 Display
120 Housing
121 Surface
122 First slope portion
130 Wireless relay apparatus
140 Base
141 Wall portion
142 Recess portion
143 Recess portion
144 Protruding portion (first protruding portion)
145 Protruding portion
146 Support portion
150 Connecting portion
152 First member
154 Second member
156 Hinge portion

What is claimed is:

1. A display apparatus comprising:
a display; and
a support member that supports the display, wherein
the support member includes a base, and
the base includes, on an upper surface thereof, a positioning portion that positions a first input device.

2. The display apparatus according to claim 1, wherein
the positioning portion includes a recess portion formed in the upper surface.

3. The display apparatus according to claim 2, wherein
the recess portion is larger than the first input device in a top plan view.

4. The display apparatus according to claim 2, wherein
the first input device includes a protruding portion, and
the recess portion positions the first input device by accepting the protruding portion.

5. The display apparatus according to claim 1, wherein
the positioning portion includes an anti-slip portion having a coefficient of friction larger than that of the upper surface of the base.

6. The display apparatus according to claim 1, wherein
the positioning portion includes a first protruding portion.

7. The display apparatus according to claim 6, wherein
the support member includes a pillar portion extending upward from the base, and
the first input device is disposed between the first protruding portion and the pillar portion.

8. The display apparatus according to claim 6, wherein
the first input device is a keyboard,
a lower surface of the keyboard includes a second protruding portion, and,
when being used the keyboard, the keyboard is arranged in such a way that a side surface of the first protruding portion and a side surface of the second protruding portion come into contact with each other.

9. The display apparatus according to claim 1, further comprising:
at least one memory configured to store instructions;
at least one processor configured to execute the instructions to perform operations comprising controlling the display; and
a housing that the at least one memory and the at least one processor, wherein
at least a part of a back surface of the display faces a side surface of the housing,
an upper surface of the housing includes a slope portion being tilted in a thickness direction of the display, and
a ratio of the slope portion with respect to the upper surface is 50% or more.

10. The display apparatus according to claim 1, further comprising:
at least one memory configured to store instructions;
at least one processor configured to execute the instructions to perform operations comprising controlling the display; and
a housing that accommodates the at least one memory and the at least one processor, wherein
a side surface of the housing includes a recess portion that holds a second input device.
